(19) United States
(12) Patent Application Publication
(10) Pub. No.: US 2009/0184371 A1
(43) Pub. Date: Jul. 23, 2009

(54) SEMICONDUCTOR DEVICE WITH AN SOI STRUCTURE

(76) Inventor: Shigeru KAWANAKA, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/352,075

(22) Filed: Jan. 12, 2009

(30) Foreign Application Priority Data
Jan. 17, 2008 (JP) 2008-008286

(51) Int. Cl. H01L 27/12

(52) U.S. Cl. 257/347; 257/E27.112

(57) ABSTRACT

A first element includes a first diffused layer which is formed in the element forming film so as to reach an insulating film, a second diffused layer which is formed in the element forming film so as not to reach the insulating film, and a first body region formed between the first and the second diffused layers. A second element, which is formed on the element forming film so as to be adjacent to the first element, includes the second diffused layer, a third diffused layer which is formed in the element forming film so as to reach the insulating film, and a second body region formed between the second and the third diffused layers. A connection part connects the body region of the first element and the body region of the second element to each other electrically.

### CROSS-REFERENCE TO RELATED APPLICATIONS

This application is based upon and claims the benefit of priority from prior Japanese Patent Application No. 2008-008286, filed Jan. 17, 2008, the entire contents of which are incorporated herein by reference.

### BACKGROUND

In the related art, JP 2001-352077 has disclosed a field-effect transistor where the source/drain diffused layer formed in an SOI layer is set to a depth not reaching the underlying insulating layer. In JP 2001-352077, the following has been disclosed: the body regions of four field-effect transistors of the same conductivity type are set to the same potential as that of the SOI layer. In this case, the four transistors cannot exhibit the advantage of SOI elements sufficiently due to the same substrate bias effect as that of normal bulk elements.

### BRIEF SUMMARY OF THE INVENTION

According to an aspect of the invention, there is provided a semiconductor device comprising: a substrate which has an element forming film on an insulating film; a first element which is formed on the element forming film and which includes a first impurity diffused layer formed in the element forming film and reaching the insulating film, a second impurity diffused layer formed in the element forming film and not reaching the insulating film, and a first body region formed between the first impurity diffused layer and the second impurity diffused layer in the element forming film; a second element which is formed on the element forming film so as to be adjacent to the first element and which includes the second impurity diffused layer, a third impurity diffused layer formed in the element forming film and reaching the insulating film, and a second body region formed in the element forming film between the second impurity diffused layer and the third impurity diffused layer; and a connection part which is formed in the element forming film below the second impurity diffused layer and which connects the body region of the first element and the body region of the second element electrically.

### BRIEF DESCRIPTION OF THE SEVERAL VIEWS OF THE DRAWING

FIGS. 1-9 are diagrams to explain a process of manufacturing an SRAM according to the embodiment of the invention;

FIG. 10 is a circuit diagram of a 6-Tr SARM cell according to the embodiment;

FIG. 11 is a plan view of a first SRAM cell array according to the embodiment;

FIG. 12 is a plan view of a second SRAM cell array according to the embodiment;

FIG. 13 is a plan view of a third SRAM cell array according to the embodiment;

FIG. 14 shows the relationship between body potentials in the individual PD-SOI elements in an SRAM of the conventional art and of the embodiment;

FIG. 15 shows the relationship between body potentials in the individual PD-SOI elements in an SRAM of the conventional art and that of the embodiment;

FIG. 16 shows the correlation between body potentials in the individual PD-SOI elements in an SRAM of the conventional art and that of the embodiment;

FIG. 17 is a circuit diagram of a 2-input NAND gate formed using PD-SOI elements of the embodiment; and

FIG. 18 is a circuit diagram of a 2-input NAND gate formed using PD-SOI elements as a comparison example.

### DETAILED DESCRIPTION OF THE INVENTION

Hereinafter, referring to the accompanying drawings, an embodiment of the invention will be explained.

When an SOI element configured as described above serves as a bulk planar element, the junction capacitance existing between the source and drain regions and the Si substrate is reduced remarkably. Moreover, in the SOI element, the potential in the MOSFET body region is set to a potential independent of the Si support substrate. Accordingly, a rise in the threshold voltage caused by the body effect can be suppressed, which enables the element performance to be improved.

However, if the SOI element with the above configuration is not a bulk planar element, a problem will arise. For example, if SOI-MOSFET elements constitute a static RAM (SRAM), since the body region of a pair of adjacent transfer transistors connected to two memory nodes of an SRAM cell is independent of the body region of a pair of adjacent driver transistors, the body regions have different body potentials. Accordingly, the threshold voltage of the transfer transistor pair differs from that of the driver transistor pair.

If the mismatch between the threshold voltages of those transistors has occurred, the static noise margin (SNM), an index of data-retention stability of the SRAM cell, decreases. The SNM shows the capability of, when data “0” or “1” is written to a cell, retaining the written data with no change even if another cell sharing the word line with the cell is accessed.

For example, consider a case where the data in the selected SRAM cell which shares a word line with an unselected SRAM cell is read. Suppose the potential at a memory node to which one end of the transfer transistor of the unselected SRAM cell is connected is at either the ground potential Vss or a power supply voltage Vdd according to the stored data “0” or “1.” Further suppose the potentials of a pair of bit lines to which the other end of the transfer transistor is connected are both at the power supply voltage Vdd. Still further suppose the potential of a word line, that is, the potential of the gate electrode of the transfer transistor is at Vss. In this case, the amount of charge accumulated in one of the body regions of the transfer transistors making the pair differs from that of the other, making the body potentials of the transfer transistors different from each other. That is, the body potential of the transfer transistor connected to a memory node which has stored data “0” drops toward ground potential, whereas the body potential of the transfer transistor connected to a memory node which has stored data “1” has a potential close to the power supply voltage. When the body potential drops, the threshold voltage of the transistor rises. When the body potential rises, the threshold voltage of the transistor drops. Accordingly, the threshold voltages of these transistors differ.

On the other hand, in a pair of driver transistors, since the driver transistor connected to a memory node which has stored data “0” is in the on state, its body potential drops toward ground potential and the threshold voltage has risen. Moreover, since the driver transistor connected to a memory node which has stored data “1” is in the off state, its body potential is at a value close to the power supply voltage and the threshold voltage has dropped. Accordingly, the threshold voltages of these transistors differ.

In the above state, when a cell sharing a word line with this cell is selected, the word line is set to Vdd. In this case, since the transfer transistor and driver transistor which are connected to a memory node storing data “0” both have a high threshold voltage, their current driving capability decreases even if they are turned off. Thus, the potential of a bit line cannot be discharged at high speed, with the result that the potential of a memory node storing data “0” rises. On the other hand, although the driver transistor connected to a memory node storing data “1” is in the off state, its current driving capability increases since its threshold voltage is low as described above. Consequently, even if the potential at the memory node storing data “0” rises slightly, the driver transistor might go on, resulting in the inversion of data. As described above, when an SRAM is composed of SOI-MOSFET elements, a problem arises: the SNM deteriorates due to the mismatch between the threshold voltage of a pair of transfer transistors and the threshold voltage of a pair of driver transistors.

Furthermore, the higher the cell access speed can be made, the greater the total current driving power of the transfer transistor and driver transistor connected to a bit line. However, in the case of an SRAM composed of the conventional SOI-MOSFET elements, the threshold voltages of the transfer transistor and driver transistor connected to a memory node storing data “0” particularly become high. Thus, the total current driving power decreases, which makes it difficult to increase the access speed. Accordingly, a semiconductor device has been desired which is capable of suppressing a rise in the threshold voltage of the element and preventing the mismatch between the threshold voltages of adjacent elements.

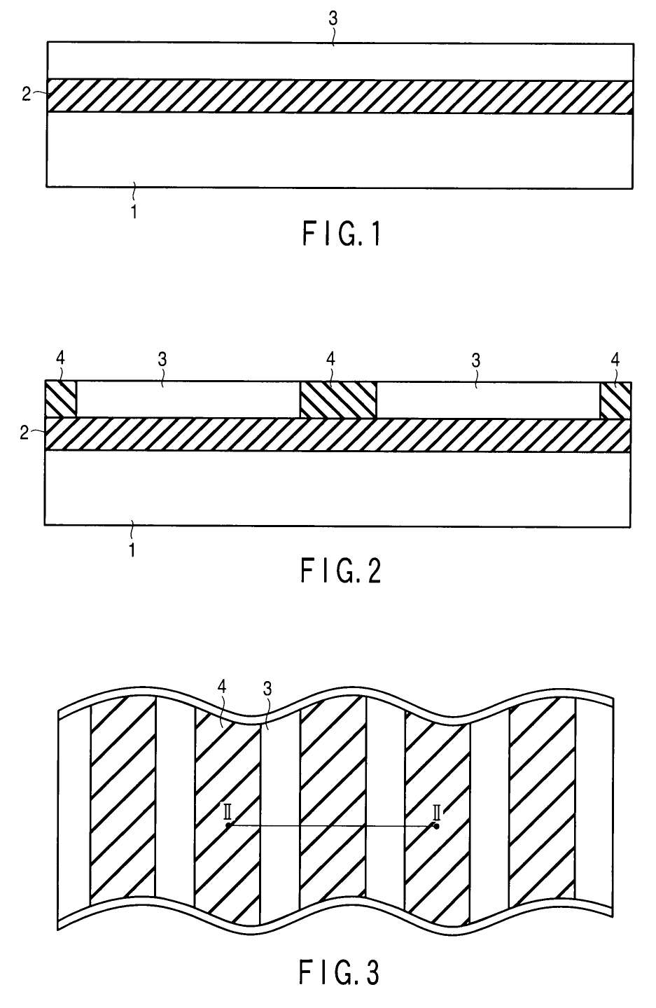

FIGS. 1 to 9 are diagrams to help explain the process of manufacturing an SRAM, a semiconductor device, according to an embodiment of the invention. FIGS. 1, 2, 4, 6, 7, and 9 are sectional views and FIGS. 3, 5, and 8 are plan views. For convenience of explanation, the process of manufacturing NMOSFETs constituting a transfer transistor and a driver transistor in an SRAM cell will be described, whereas the process of manufacturing PMOSFETs constituting a load transistor in the SRAM cell will be omitted.

First, as shown in FIG. 1, an SOI wafer is prepared by separation by implantation of oxygen (SIMOX) techniques or lamination techniques. In the SOI wafer, a buried oxide film (BOX) 2 composed of an SiO₂ film is stacked on an Si semiconductor substrate 1. On the BOX, an SOI active layer 3 (element forming film) is stacked. Thereafter, the SOI active layer 3 is thinned to a desired thickness, for example, about 100 nm, by thermal oxidation techniques and by etching using NH₄F.

Next, as shown in FIG. 2, a plurality of element isolating regions 4 for electrically separating individual SOI elements are formed by shallow trench isolation (STI) techniques. FIG. 3 is a plan view and FIG. 2 is a sectional view taken along line II-II of FIG. 3.

Next, for example, p-type impurity ions for adjusting the threshold voltage of the element are implanted into the SOI active layer 3.

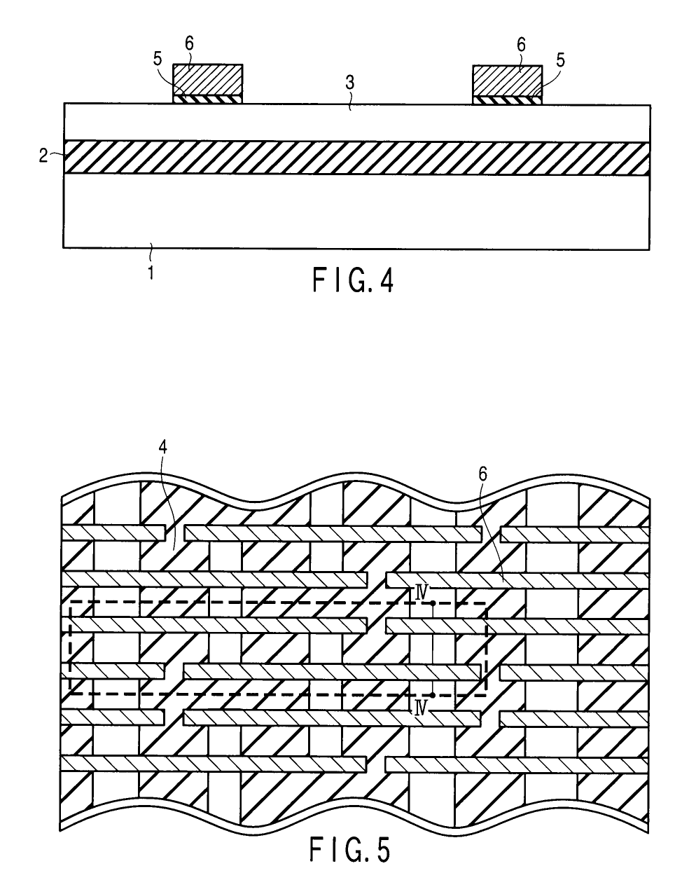

Thereafter, as shown in FIG. 4, on the SOI active layer 3, a silicon oxide film to serve as a gate insulating film 5 is formed by thermal oxidation techniques. On the silicon oxide film, a polysilicon to serve as a gate electrode 6 is deposited to a desired thickness by chemical vapor deposition (CVD) techniques.

Next, with a resist or the like as a mask, the polysilicon and silicon oxide film are processed by reactive ion etching (RIE), thereby forming a gate electrode 6 and a gate insulating film 5 shown in FIG. 4. FIG. 5 is a plan view of FIG. 4. FIG. 4 is a sectional view taken along line IV-IV line of FIG. 5.

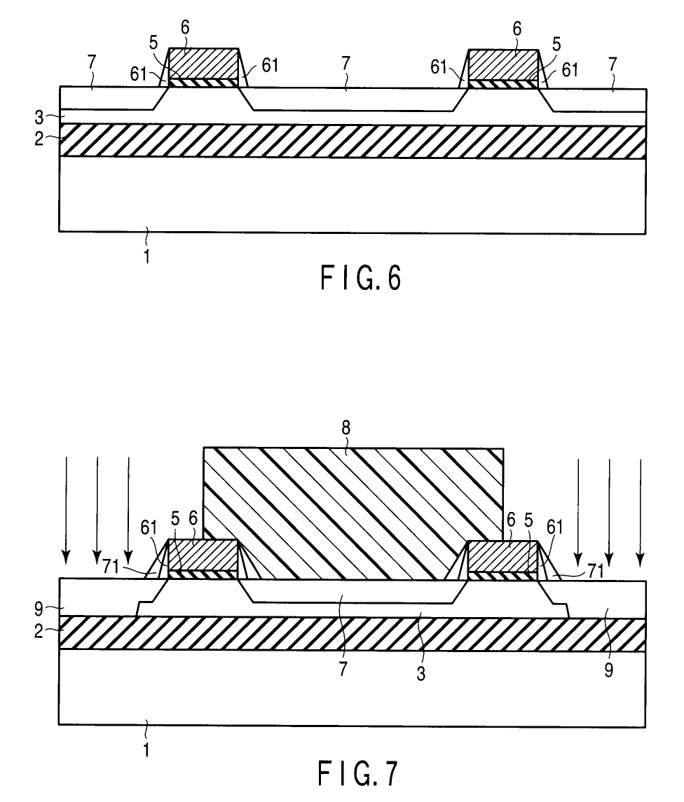

Thereafter, as shown in FIG. 6, a first sidewall insulating film 61 is formed on the sidewall of each gate electrode 6. In this case, first, a silicon oxide film (SiO₂ film) is deposited by CVD techniques or the like. The formed SiO₂ film is etched anisotropically by RIE techniques, thereby forming a first sidewall insulating film 61. In this state, with the gate electrode 61 and first sidewall insulating film 61 as a mask, ions are implanted into the source and drain regions, thereby forming, for example, a first impurity diffused layer 7 of the n type. At this time, ion implantation conditions are selected so as to prevent the first impurity diffused layer 7 from reaching the BOX 2 even after a subsequent activation annealing process or the like. For example, if the thickness of the SOI active layer 3 is 100 nm and the thickness of the first impurity diffused layer 7 is 40 nm, the condition for As implantation is that, for example, the accelerating voltage is 3 keV and the dose amount is 2×10¹⁵/cm². Thereafter, for example, in an activation annealing process using rapid thermal anneal (RTA) techniques, for example, heat treatment is performed at a heating temperature of 1000° C. for 3 seconds.

Next, as shown in FIG. 7, a second sidewall insulating film 71 is formed on the sidewall of each gate electrode 6. In this case, an SiO₂ film is deposited on the entire surface by, for example, CVD techniques. Next, a silicon nitride film (Si₃N₄ film) is similarly deposited by, for example, CVD techniques. Thereafter, the Si₃N₄ film and SiO₂ film are etched anisotropically by RIE techniques, thereby forming a second sidewall insulating film 71 on the first sidewall insulating film 61. In this state, resist 8 is applied. The resist 8 is patterned so as to cover the diffused layer between two specific gate electrodes 6. With the patterned resist 8 as a mask, for example, n-type impurity ions are implanted into the active layer 3, thereby forming a second impurity diffused layer 9 in the region excluding the region between the two gate electrodes 6, specifically, in the region corresponding to the source region of the left element and the region corresponding to the drain region of the right element in FIG. 7. At this time, ion implantation conditions are selected so that the second impurity diffused layer 9 may reach the BOX 2 after a subsequent activation annealing process. The condition for As implantation is that, for example, the accelerating voltage is 60 keV and the dose amount is 5×10¹⁵/cm². In FIG. 7, the first impurity diffused layer 7 corresponds to the drain region of the left element and the source region of the right element.

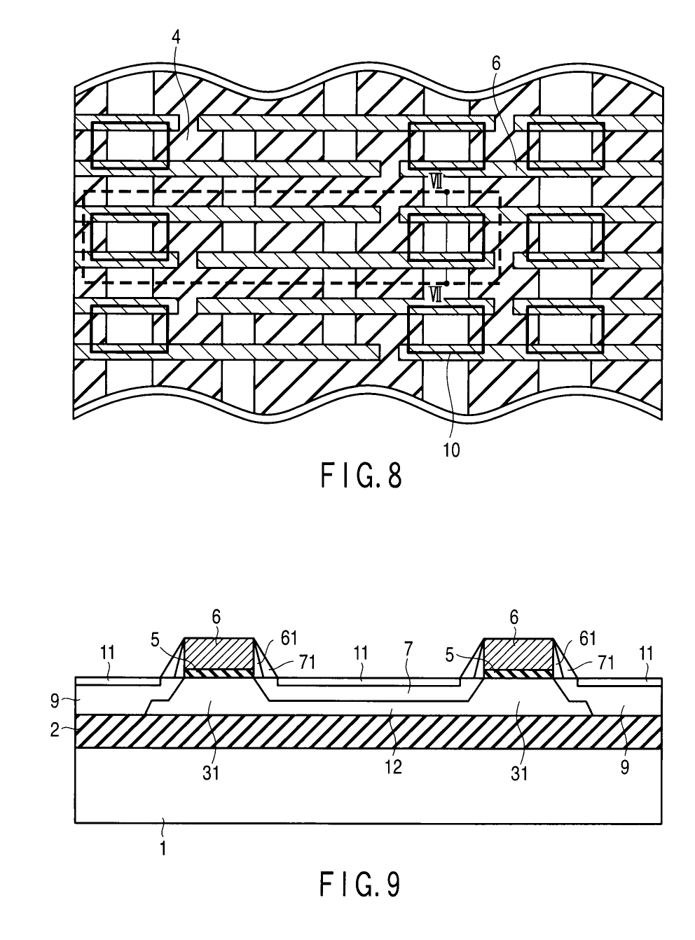

FIG. 8 is a plan view corresponding to FIG. 7. Numeral 10 indicates a region covered with the resist 8. The resist part covering a region where a PMOSFET is to be formed is not shown. FIG. 7 is a sectional view taken along line VII-VII of FIG. 8.

In this state, the resist 8 shown in FIG. 7 is peeled and an annealing process for activating the impurities introduced by ion implantation is carried out.

Thereafter, as shown in FIG. 9, a silicide layer 11 is formed on the first impurity diffused layer 7 and second impurity diffused layer 9, thereby forming a PD-SOI element.

In the PD-SOI element formed in this way, the body regions 31, 31 of adjacent elements are connected electrically to each other via a connection region 12 (a connection part) formed below the first impurity diffused region 7 as shown in FIG. 9. For this reason, the connected body regions are set to the same potential. Each of the body regions is in the floating state and its potential is not fixed to such an external potential as the GND potential.

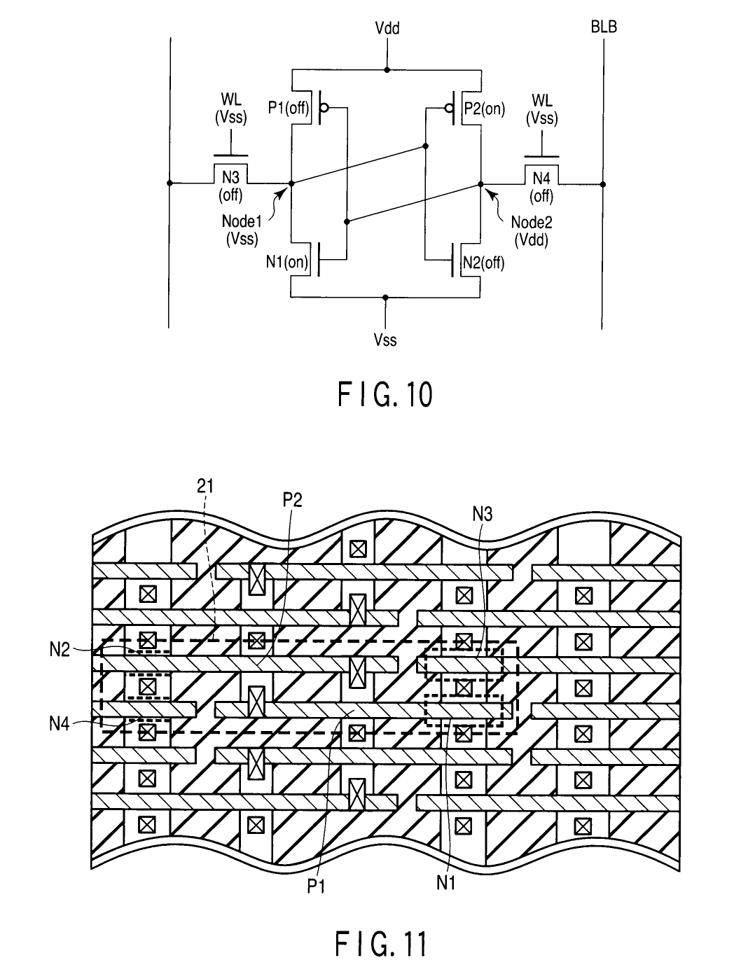

FIG. 10 is a circuit diagram of a 6Tr-SARM formed by combining six elements. In FIG. 10, N1 and N2 indicate driver transistors, N3 and N4 indicate transfer transistors (Tr) and P1 and P2 are load transistors that supply power to the driver transistors.

FIG. 11 is a plan view of an SRAM cell array formed using transistors configured as described above. The same parts as those of FIG. 10 are indicated by the same reference numerals. In FIG. 11, a region indicated by a broken line 21 is an SRAM cell composed of six transistors. A transfer transistor N3 and a driver transistor N1 are formed so as to be adjacent to each other sharing the body region as the two elements shown in FIG. 9 are. A transfer transistor N4 and a driver transistor N2 are also formed so as to be adjacent to each other sharing the body region. Between the transistors N3, N1 and the transistors N4, N2, PMOS transistors P1, P2 for supplying power to the driver transistors N1, N2 are formed. Each of the transistors N1, N2, N3, N4, P1, P2 in the SRAM cell shares one of the source and drain regions with each of the transistors of an adjacent cell.

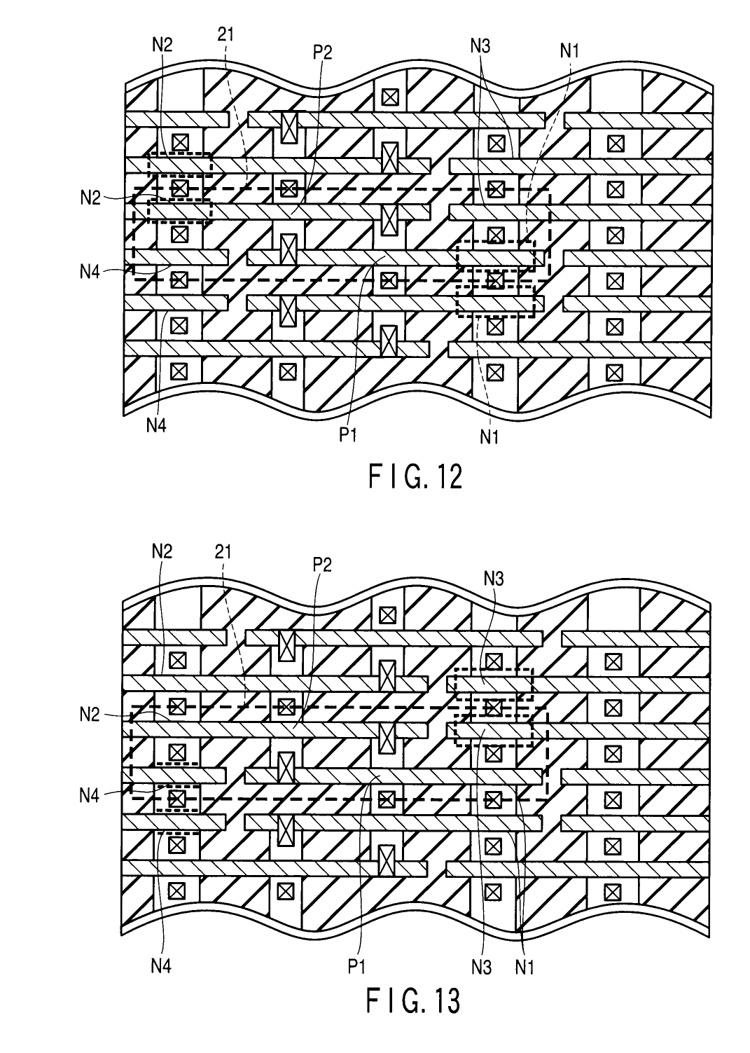

Each of FIGS. 12 and 13 shows the relationship between an SRAM cell shown by the broken line 21 and the transistors of an adjacent cell. The same parts as those of FIGS. 10 and 11 are indicated by the same reference numerals.

In the configuration of FIG. 11, the body regions of the transfer transistor and driver transistor in one cell are connected to each other. In contrast, FIG. 12 shows a case where the body regions of the driver transistors N1, N2 of the SRAM cell shown by the broken line 21 are connected to the body regions of the driver transistors N1, N2 of an adjacent cell, respectively.

As shown in FIG. 12, the driver transistor N1 of the SRAM cell shown by the broken line 21 and the driver transistor N1 of an adjacent cell share the body region and the driver transistor N2 of the SRAM shown by broken line 21 and the driver transistor N2 of an adjacent cell share the body region. Therefore, the body potential of the driver transistors N1, N1 of these adjacent cells and the body potential of the driver transistors N2, N2 of the adjacent cells are practically equal. Accordingly, the mismatch between the threshold voltages of the driver transistors N1, N1 of adjacent cells and between the threshold voltages of the driver transistors N2, N2 can be prevented.

FIG. 13 shows a case where the body regions of the transfer transistors N3, N4 of the SRAM cell shown by the broken line 21 are connected to the body regions of the transfer transistors N3, N4 of an adjacent cell, respectively. That is, as shown in FIG. 13, the transfer transistor N3 of the SRAM cell shown by the broken line 21 and the transfer transistor N3 of an adjacent cell share the body region and the transfer transistor N4 of the SRAM cell shown by the broken line 21 and the transfer transistor N4 of the adjacent cell share the body region. Therefore, the body potentials of the adjacent driver transistors N3, N3 and the body potentials of the adjacent driver transistors N4, N4 are practically equal. Accordingly, the mismatch between the threshold voltages of the driver transistors N3, N3 of adjacent cells and between the threshold voltages of the driver transistors N4, N4 of the adjacent cells can be prevented.

As described above, FIG. 12 shows a case where the body regions of the driver transistors N1, N2 of adjacent cells are connected to each other. FIG. 13 shows a case where the body regions of the transfer transistors N3, N4 of adjacent cells are connected to each other. These may be combined in such a manner that the body regions of the driver transistors N1, N2 of adjacent cells are connected to the body regions of the transfer transistors N3, N4 of the adjacent cells.

In FIGS. 11 to 13, the size of the driver transistors N1, N2 and the size (e.g., channel width) of the transfer transistors N3, N4 are shown the same. Actually, however, the size of the driver transistors N1, N2 is set larger than the size of the transfer transistors N3, N4 so that the current driving power of the driver transistors N1, N2 may be higher than that of the transfer transistors N3, N4.

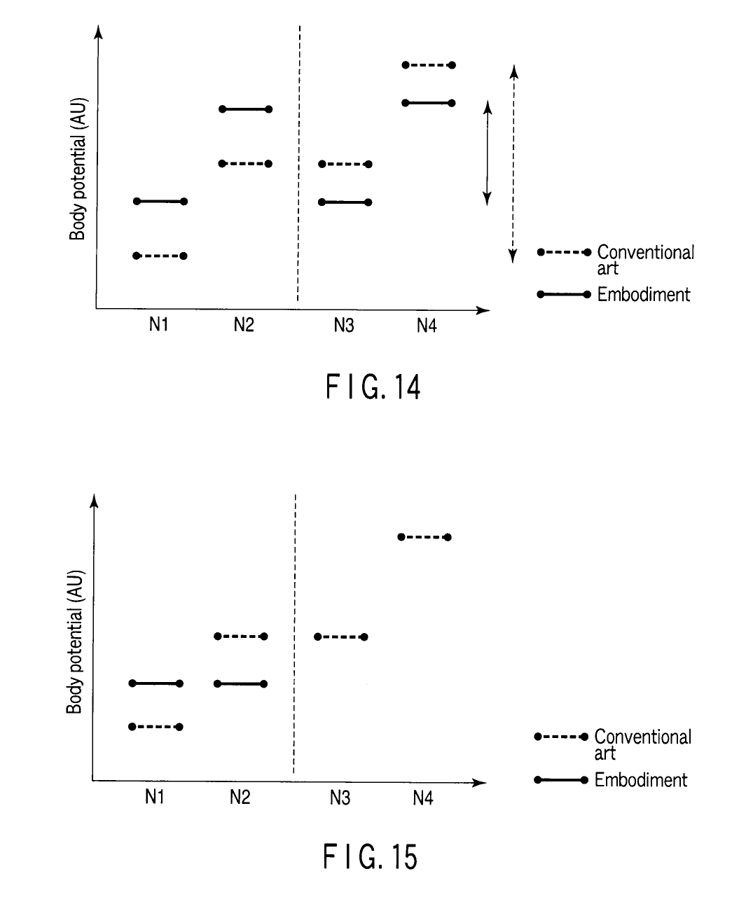

FIGS. 14 to 16 show the relationship between the body potentials of the transistors constituting an SRAM cell of the embodiment and of the transistors constituting a conventional SRAM cell. In FIGS. 14 to 16, the solid lines indicate the body potentials of transistors N1, N2, N3, N4 constituting an SRAM cell of the embodiment and the broken lines indicate the body potentials of transistors N1, N2, N3, N4 in a case where the body regions constituting a conventional SRAM cell are not connected to one another. Suppose the configuration of the SRAM cell and the relationship between data stored in the cell and its internal potential are the same as those in FIG. 10.

FIG. 14, which corresponds to FIG. 11, shows the body potential of each transistor in one SRAM cell. As shown in FIG. 11, in one cell, the body region of transfer transistor N3 and that of driver transistor N1 are connected electrically to each other and the body region of transfer transistor N4 and that of driver transistor N2 are connected electrically to each other. Therefore, as shown by the solid lines in FIG. 14, the body potentials of transistors N1 and N3 are the same and the body potentials of transistors N4 and N2 are the same. The body potential of transistors N1 and N3 lies between the body potential of transistor N1 and the body potential of transistors N2 and N3 in the conventional SRAM cell. The body potential of transistors N4 and N2 lies between the body potential of transistor N4 and the body potential of transistors N2 and N3 in the conventional SRAM cell. The body potentials of transistors N1 to N4 vary depending on the data stored in an adjacent SRAM cell. However, the range of the body potentials of transistors N1 to N4 is as shown by the solid-line arrow in FIG. 14 as described later. Transistors N1 to N4 will never have the body potential of the conventional transistor N1 or that of the conventional transistor N4 in the range shown by the broken-line arrow in FIG. 14.

Moreover, in an SRAM cell of the embodiment, the difference in body potential between transistor N1 and transistor N2 is almost equal to the difference in body potential between transistor N3 and transistor N4. In addition, as shown by the solid-line arrow in FIG. 14, the body potential range is narrower than the conventional body potential range shown by the broke line. This means that variations in the threshold voltages of transistors N1 to N4 are suppressed. From this, it is seen that the mismatch between the threshold voltages of transistors N1 to N4 is suppressed.

As described above, to improve the SNM of an SRAM cell, it is necessary to suppress the mismatch between the threshold voltages of driver transistors N1, N2 constituting a pair and further suppress the mismatch between the threshold voltages of transfer transistors N3, N4.

Furthermore, to increase the access speed of the SRAM cell, it is necessary to improve the total current driving power of the transfer transistor and driver transistor. It is particularly important to improve the total current driving power of the transfer transistor and driver transistor connected to a memory node which has stored data “0.” That is, it is necessary to improve the current driving power of transfer transistor N3 and driver transistor N1 connected to a bit line BL shown in FIG. 10.

In the embodiment, the body potential of driver transistor N1 connected to memory node Node1 which has stored data “0” is made higher than the conventional transistor N1 shown by a broken line by the body potential of transfer transistor N3, which makes the threshold voltage lower. Therefore, the current driving power of driver transistor N1 is improved more than the conventional equivalent. Moreover, since the body potential of transfer transistor N3 has dropped below that of the conventional transistor N3 shown by a broken line, the threshold voltage is higher than the conventional threshold voltage. Furthermore, the transfer transistor N4 has made the body potential of driver transistor N2 higher than that of the conventional transistor N2 shown by a broken line. Thus, the threshold voltage of transistor N2 is lower than that of the conventional equivalent. In addition, the body potential of transfer transistor N4 is lower than that of the conventional equivalent. Therefore, the threshold voltage of transistor N4 is higher than that of the conventional equivalent.

In this state, when a word line is set at Vdd, the transfer transistors N3, N4 are turned on. Since a PMOSFET P2 supplies the power supply voltage Vdd to the gate electrode of driver transistor N1 whose current driving power has been improved as compared with the conventional equivalent, memory node Node1 is pulled down strongly to Vss. In addition, transfer transistor N3 whose current driving power has been made lower than that of the conventional equivalent raises the potential of memory node Node1 at a lower speed than the conventional equivalent. On the other hand, although driver transistor N2 has improved current driving power as compared with the conventional equivalent, the turning on of driver transistor N2 is suppressed since the potential of memory node Node1 is pulled down at high speed. Accordingly, the data inversion at a memory node can be prevented, thereby improving the SNM as compared with the conventional equivalent.

In a case where the stored data is read in the state shown in FIG. 10, when transfer transistors N3, N4 are turned on, transfer transistor N3 and driver transistor N1 discharge the potential of the bit line BL to Vss at high speed. In the conventional equivalent, the threshold voltage of transfer transistor N3 and that of driver transistor N1 were both high, whereas, in the embodiment, the threshold voltage of driver transistor N1 is made lower, improving the current driving power. Accordingly, the data reading speed can be made higher.

Although the threshold voltage of transfer transistor N3 is higher than the conventional equivalent, the current driving power of driver transistor N1 whose size is larger than that of transfer transistor N3 is increased. Consequently, the total current driving power has been improved as compared with the conventional equivalent, which enables the data access speed to be improved.

Since transfer transistor N4 and driver transistor N2 connected to a memory node which has stored data “1” have only to maintain the potential of the bit line BLB at Vdd, they do not contribute to increasing the data reading speed.

With the above configuration, the body regions of transistors N3, N1 serving as adjacent PD-SOI elements in an SRAM cell are connected to each other and the body regions of transistors N4, N2 are connected to each other, thereby making the body potentials of adjacent transistors practically equal. That is, the body regions of transfer transistors N3, N4 which have a high body potential are connected to the body regions of driver transistors N1, N2 which have a lower body potential than transfer transistors N3, N4, thereby suppressing a drop in the body potentials of driver transistors N1, N2. Accordingly, the threshold voltage of driver transistor N1 can be made higher, which enables the SNM to be improved.

Furthermore, since the threshold voltages of transistors N3, N1 can be made equal and the total current driving power of transistors N3, N1 can be improved, the access speed can be made higher.

FIG. 15, which corresponds to FIG. 12, shows the body potential of each transistor included in one cell in a case where the body regions of the driver transistors N1, N1 of adjacent cells are connected electrically to each other and the body regions of the driver transistors N2, N2 are connected electrically to each other. In FIG. 15, the solid lines show a case where adjacent cells each of which includes driver transistor N1 whose body region is connected electrically to the other body region store different data items and adjacent cells each of which includes driver transistor N2 whose body region is connected electrically to the other body region store different data items. That is, for example, suppose driver transistor N1 included in a cell in a region shown by a broken line 21 in FIG. 12 is on, driver transistor N1 in a cell adjacent to the driver transistor N1 is off, driver transistor N2 included in a cell in the region shown by the broken line 21 is off, and driver transistor N2 in a cell adjacent to the driver transistor N2 is on.

As shown by the solid lines in FIG. 15, in the embodiment, the body potential of driver transistor N1 included in a cell in the region shown by the broken line of FIG. 12 has risen above the conventional body potential shown by the broken line, since the body potential of driver transistor N1 in the adjacent cell is high. Moreover, the body potential of driver transistor N2 included in a cell in the region shown by the broken line 21 of FIG. 12 has dropped below the conventional body potential shown by the broken line, since the body potential of driver transistor N2 in the adjacent cell is low. As a result, the body potentials of driver transistors N1, N2 are the same.

As described above, when the body potentials of driver transistors N1, N2 are the same, the threshold voltages of these transistors are also almost the same. Accordingly, the SNM representing the data retention characteristic can be improved. Furthermore, since the threshold voltage of driver transistor N1 connected to memory node Node1 which has stored data “0” has dropped, the data reading speed can be increased.

As described above, in the embodiment, the body regions of driver transistor N1, N1 of adjacent cells are connected to each other and the body regions of driver transistor N2, N2 are connected to each other. Consequently, when the data items stored in adjacent cells differ from each other, the body potentials of driver transistors N1, N1 and the body potentials of driver transistors N2, N2 in adjacent cells are the same and the threshold voltages of driver transistors N1, N2 are the same. Accordingly, the SNM and the data reading speed can be improved.

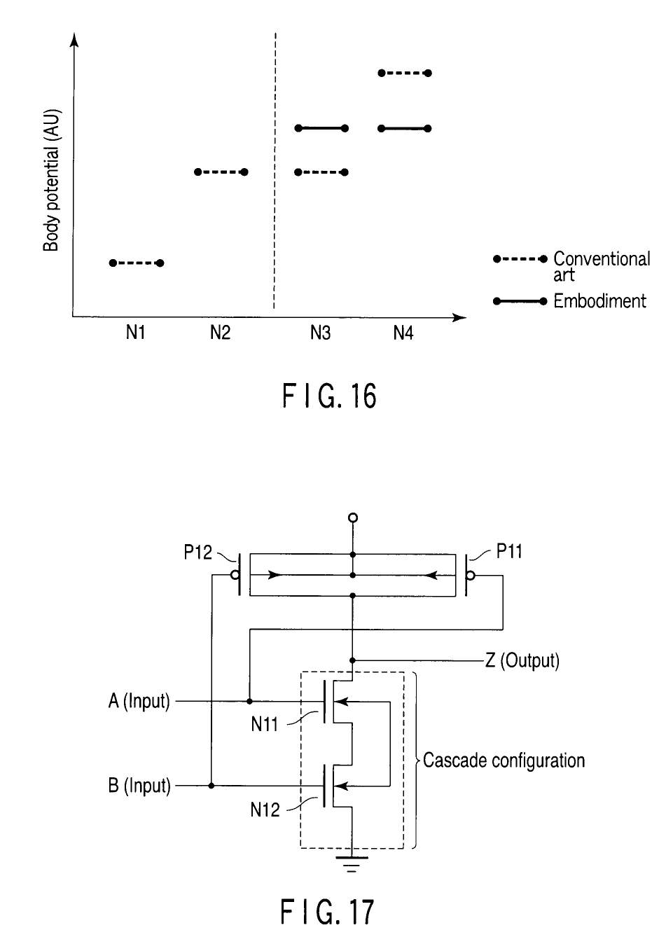

FIG. 16, which corresponds to FIG. 13, shows the body potential of each transistor included in one cell in a case where the body regions of transfer transistors N3, N3 are connected electrically to each other and the body regions of transfer transistors N4, N4 in adjacent cells are connected electrically to each other. In FIG. 16, the solid lines show a case where adjacent cells each of which includes transfer transistor N3 whose body region is connected electrically to the other body region store different data items and adjacent cells each of which includes transfer transistor N4 whose body region is connected electrically to the other body region store different data items.

That is, for example, when memory node Node1 connected to transfer transistor N3 included in a cell in the region shown by the broken line 21 in FIG. 13 has stored data “0” and memory node Node1 connected to transfer transistor N3 in a cell adjacent to the transfer transistor N3 has stored data “1,” the body potential of transfer transistor N3 included in the cell in the region shown by the broken line 21 of FIG. 13 has risen as shown by the solid line in FIG. 16 above the conventional body potential shown by the broken line.

When memory node Node2 to which transfer transistor N4 included in a cell in the region shown by the broken line 21 of FIG. 13 has stored data “1” and memory node Node2 to which transfer transistor N4 included in a cell adjacent to the transfer transistor N4 has stored data “0,” the potential of transfer transistor N4 is lower than that of transfer transistor N4 in the adjacent cell and therefore drops below the conventional body potential shown by the broken line. As a result, the body potentials of transfer transistors N3, N4 are almost the same.

As described above, connecting the body regions of adjacent cells to each other enables the body potentials of transfer transistors N3, N4 to be equal when the data items stored in the adjacent cells differ, which makes it possible to prevent the mismatch between the threshold voltages. Accordingly, the SNM can be improved.

As for transfer transistor N3, since its body potential rises, its threshold voltage drops. Therefore, transfer transistor N3, together with driver transistor N1, can improve the total current driving power and increase the cell access speed.

(Modification)

Next, a modification of the embodiment will be explained. In the modification, the embodiment is applied to a 2-input NAND gate (multistage circuit).

When a multistage circuit composed of a plurality of MOSFETs connected in series, such as a NAND gate, is configured using SOI elements, the potential of the body region of each MOSFET is set to a potential independent of the Si support substrate. Accordingly, the threshold voltage does not rise due to the body effect, which helps improve the element performance. However, in a logic circuit, such as a NAND gate, using conventional SOI elements, the potential of the body region of each MOSFET is not fixed. Therefore, the element characteristic, for example, the threshold voltage, of each MOSFET fluctuates as a result of the element being turned on or off according to the input data. Accordingly, when the threshold voltage of the element rises, the following problems arise: the current driving power decreases and the operating speed drops.

Hereinafter, the effect of using the configuration of a PD-SOI element of the embodiment will be explained in comparison with a case where conventional PD-SOI elements are used.

FIG. 17 shows a 2-input NAND gate formed using PD-SOI elements of the embodiment. In FIG. 17, n-type transistors N11, N12 are connected in series between an output terminal Z and ground. Input signals A, B are supplied to the gates of the transistors N11, N12, respectively. Moreover, p-type transistors P11, P12 are connected in parallel between a power supply terminal and the output terminal Z. The input signals A, B are supplied to the gates of the transistors P11, P12.

The body regions of n-type transistors N11, N12 constituting a multistage circuit are connected electrically to each other and are set in a floating state. Here, n-type transistors N11, N12 correspond to two elements shown in FIG. 9, respectively, and further correspond to, for example, transistors N3, N1 in FIG. 10, respectively.

In FIG. 17, for example, when input signal A is “1” and input signal B is “0,” n-type transistor N11 on the output terminal Z side is on, transistor N12 is off, transistor P11 is off, and transistor P12 is on, with the result that the output terminal Z is at “1.” Accordingly, the body potential of transistor N12 approaches ground potential, whereas the body potential of transistor N11 approaches the power supply voltage at the output terminal Z. Since the body regions of the transistor N11 and N12 are connected to each other, a drop in the body potential of transistor N12 can be prevented, with the result that the body potentials of transistors N11 and N12 become practically the same. Therefore, variations in the body potentials of transistors N11 and N12 can be decreased, which suppresses a rise in the threshold voltage of transistor N12. Accordingly, the mismatch between the threshold voltages of transistors N11 and N12 can be prevented. For example, when the state of this input signal changes to a state where input signal A is at “1” and input signal B is at “1,” a decrease in the operating speed of n-type transistor N12 can be prevented.

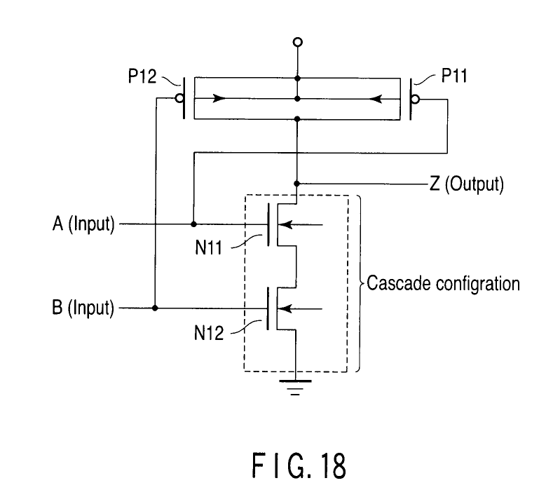

In contrast, in the case of a 2-input NAND gate using PD-SOI elements shown in FIG. 18, the body regions of n-type transistors N11, N12 connected in series are separated. In this state, the body regions are made floating. Accordingly, when input signal A is at “1” and input signal B is at “0,” the body potential of transistor N11 in the on state approaches the power supply voltage, with the result that the threshold voltage of transistor N11 drops. In addition, the body potential of transistor N12 in the off state approaches ground potential, with the result that the threshold voltage of transistor N12 rises. As described above, the mismatch between the threshold voltages of transistors N11 and N12 occurs. Therefore, when this state changes to a state where input signal A is at “1” and input signal B is at “1,” the operating speed of transistor N12 decreases.

While the invention has been applied to NMOSFETs constituting a NAND gate in the modification, the multistage circuit is not limited to a NAND gate. For instance, the invention may be applied to PMOSFETs constituting, for example, a NOR gate.

Furthermore, while in the embodiment, MOSFETs using an SOI substrate have been explained, the invention is not limited to this. For instance, a silicon-on-sapphire (SOS) substrate may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a substrate which has an element forming film on an insulating film;
a first element which is formed on the element forming film and which includes a first impurity diffused layer formed in the element forming film and reaching the insulating film, a second impurity diffused layer formed in the element forming film and not reaching the insulating film, and a first body region formed between the first impurity diffused layer and the second impurity diffused layer in the element forming film;
a second element which is formed on the element forming film so as to be adjacent to the first element and which includes the second impurity diffused layer, a third impurity diffused layer formed in the element forming film and reaching the insulating film, and a second body region formed in the element forming film between the second impurity diffused layer and the third impurity diffused layer; and
a connection part which is formed in the element forming film below the second impurity diffused layer and which connects the body region of the first element and the body region of the second element electrically.

2. The device of claim 1, wherein the semiconductor device is an SRAM, the first element is a driver transistor of the SRAM, and the second element is a transfer transistor of the SRAM.

3. The device of claim 2, wherein the potential of the body region of the first element acting as the driver transistor is equal to the potential of the body region of the second element acting as a transfer transistor.

4. The device of claim 1, wherein the semiconductor device is a static RAM (SRAM), the first element is a driver transistor in a first cell, and the second element is a driver transistor in a second cell adjacent to the first cell.

5. The device of claim 4, wherein the potential of the body region of the first element acting as the driver transistor is equal to the potential of the body region of the second element acting as a driver transistor.

6. The device of claim 1, wherein the semiconductor device is a static RAM (SRAM), the first element is a transfer transistor in a first cell, and the second element is a transfer transistor in a second cell adjacent to the first cell.

7. The device of claim 6, wherein the potential of the body region of the first element acting as the transfer transistor is equal to the potential of the body region of the second element acting as a transfer transistor.

8. The device of claim 1, wherein the first element and the second element constitute a multistage circuit.

9. The device of claim 8, wherein the multistage circuit is a NAND gate and the first element and the second element are connected in series, an input signal being supplied to the gate of each of the first and second elements, and the body region of the first element and the body region of the second element being connected to each other.

10. The device of claim 9, wherein the potential of the body region of the first element constituting the NAND gate is equal to the body region of the second element.
